(19) United States
(12) Patent Application Publication
(10) Pub. No.: US 2012/0273971 A1
(43) Pub. Date: Nov. 1, 2012

(54) SEMICONDUCTOR DEVICE AND METHOD OF MANUFACTURING THE SAME

(75) Inventor: Sensho USAMI, Tokyo (JP)

(73) Assignee: Elpida Memory, Inc.

(21) Appl. No.: 13/450,019

(22) Filed: Apr. 18, 2012

(30) Foreign Application Priority Data
Apr. 26, 2011 (JP) 2011-097732

(51) Int. Cl. H01L 23/48; H01L 23/52

(52) U.S. Cl. 257/777; 257/778; 257/E23.141; 257/E23.01

(57) ABSTRACT

Disclosed herein is a semiconductor device that comprises a wiring substrate, at least two semiconductor chips mounted on the wiring substrate, and at least one reinforcing substrate disposed so as to straddle at least portions of the two semiconductor chips.

This application is based upon and claims the benefit of priority from Japanese patent application No. 2011-97732, filed on Apr. 26, 2011, the disclosure of which is incorporated herein in its entirety by reference.

### BACKGROUND OF THE INVENTION

1. Field of the Invention

This invention relates to a semiconductor device and a method of manufacturing the same.

2. Description of Related Art

There is provided a semiconductor device adapted for high capacity which is formed in one package by mounting a plurality of semiconductor chips on a wiring substrate (JP-A-2000-315776). This type of semiconductor device is called a multi-chip package (MCP).

On the other hand, with a reduction in size and thickness of a portable electronic device or the like, there is a demand for a reduction in thickness of a semiconductor device so that a wiring substrate and a semiconductor chip are reduced in thickness.

However, with the progress in thickness reduction of the wiring substrate and the semiconductor chip, the influence of warpage of the semiconductor device becomes large. For example, in a semiconductor device in which a plurality of semiconductor chips are arranged side by side on a wiring substrate, it is necessary to provide a space (or clearance) of about 0.2 mm between the semiconductor chips for the purpose of disposing a connection pad or a passive component between the semiconductor chips. In this case, there is a problem that warpage or torsion in the form of two dents occurs between the semiconductor chips to bend the semiconductor device. Due to such warpage or torsion, when solder balls are mounted on the wiring substrate thereafter, there occurs a case where, for example, portions of the respective solder balls cannot be connected to corresponding lands of the wiring substrate or the mounting position accuracy of the solder balls onto the wiring substrate is degraded.

### SUMMARY

FIG. 1 is a cross-sectional view showing one example of a semiconductor device which was manufactured on an experimental basis for verifying the above-mentioned problem. The illustrated semiconductor device was obtained by mounting two chips 2 and 2 (thickness: 70 μm, size: 3.66 mm×7.58 mm) at a distance of 2.5 mm from each other on a substrate 1 (thickness: 190 μm, size: 15 mm×15 mm) and then sealing the mounted two chips 2 and 2 with a resin sealer 3. Then, the warpage (flatness) of the obtained semiconductor device was measured. As a result, the measurement results shown in FIG. 2 were obtained. From FIG. 2, it is seen that two dent-like concave warps 5 and 5 are formed.

The presen invention seeks to solve one or more of the above problems, or to improve upon those problems at least in part.

In one embodiment, there is provided a semiconductor device that comprises a wiring substrate, at least two semiconductor chips mounted on the wiring substrate, and at least one reinforcing substrate disposed so as to straddle at least portions of the two semiconductor chips.

In another embodiment, there is provided a semiconductor device comprising a wiring substrate including an upper surface, a first semiconductor chip mounted over the upper surface of the wiring substrate, a second semiconductor chip having a thickness that is substantially equal to that of the first semiconductor chip and mounted over the upper surface of the wiring substrate, the second semiconductor chip being apart from the first semiconductor chip, and a silicon substrate stacked so as to straddle the first and second semiconductor chips.

In still another embodiment, there is provided a semiconductor device comprising, a wiring substrate including an upper surface and a connection pad formed on the upper surface, a first semiconductor chip mounted over the upper surface of the wiring substrate, a second semiconductor chip mounted over the upper surface of the wiring substrate so as to form a space between the first and second semiconductor chips, the second semiconductor chip having a thickness that is substantially equal to that of the first semiconductor chip, a silicon substrate stacked over the first and second semiconductor chips, the space being disposed between the wiring substrate and the silicon substrate, and a sealing resin provided over the upper surface of the wiring substrate to cover the first semiconductor chip, the second semiconductor chip and the silicon substrate, the space being filled with the sealing resin.

### BRIEF DESCRIPTION OF THE DRAWINGS

The above features and advantages of the present invention will be more apparent from the following description of certain preferred embodiments taken in conjunction with the accompanying drawing, in which:

FIG. 1 is a cross-sectional view showing one example of a semiconductor device which was manufactured on an experimental basis for verifying the problem of a MCP semiconductor device;

FIG. 2 is a diagram showing the results of measuring the warpage (flatness) of the semiconductor device shown in FIG. 1;

FIG. 3 is a cross-sectional view showing a schematic structure of a semiconductor device according to a first embodiment of the present invention;

FIGS. 4A to 4F are schematic cross-sectional views for explaining the assembly flow of the semiconductor device according to the first embodiment;

FIG. 5 is a cross-sectional view showing a schematic structure of a semiconductor device according to a second embodiment of the present invention;

FIGS. 6A to 6D are schematic cross-sectional views for explaining the assembly flow of the semiconductor device according to the second embodiment;

FIGS. 7A to 7C are schematic cross-sectional views for explaining the assembly flow, following FIG. 6D, of the semiconductor device according to the second embodiment;

FIG. 8 is a cross-sectional view showing a schematic structure of a semiconductor device according to a third embodiment of the present invention;

FIG. 9 is a plan view showing a schematic structure of a semiconductor device according to a first modification of the present invention;

FIG. 10 is a cross-sectional view showing a schematic structure of a semiconductor device according to a second modification of the present invention; and

FIG. 11 is a plan view showing a schematic structure of a semiconductor device according to a third modification of the present invention.

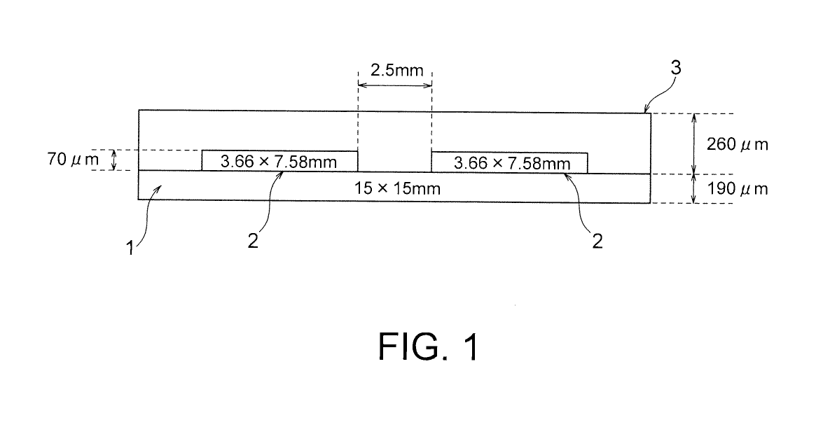

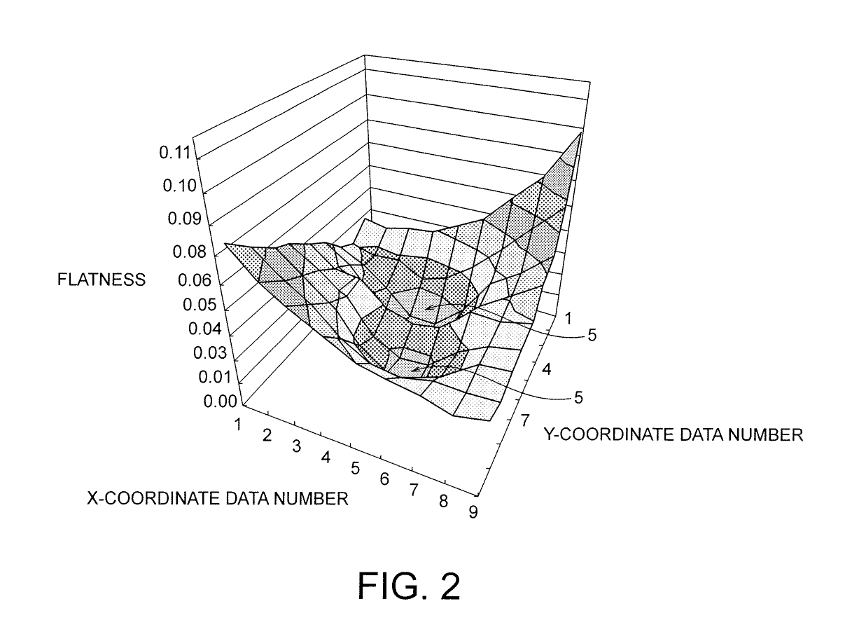

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purposes.

### First Embodiment

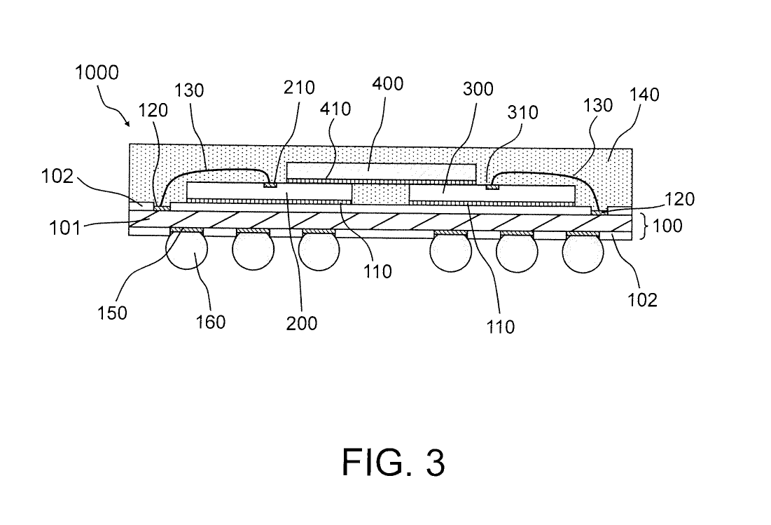

FIG. 3 is a cross-sectional view showing a schematic structure of a semiconductor device 1000 according to a first embodiment of the present invention.

In the semiconductor device 1000, first and second semiconductor chips 200 and 300 are arranged side by side on a wiring substrate 100 so as to be spaced apart from each other. Herein, the first and second semiconductor chips 200 and 300 are mounted on one surface of the wiring substrate 100 in its left and right regions through adhesive members 110 and 110 such as die attach films (DAFs), respectively. The wiring substrate 100 comprises an insulating base member 101 and insulating films 102 formed on both surfaces of the insulating base member 101. The one surface of the wiring substrate 100 is a semiconductor chip mounting surface and is formed with a plurality of connection pads 120. The other surface of the wiring substrate 100 is formed with a plurality of lands 150. The first and second semiconductor chips 200 and 300 are each formed with a predetermined circuit such as a memory circuit (illustration omitted) and with a plurality of electrode pads 210 or 310 on its one surface (herein its upper surface). The electrode pads 210 (first electrodes) or 310 (second electrodes) are arranged in one row in a central region of the corresponding first or second semiconductor chip 200 or 300 and are electrically connected to the connection pads 120 (first or second conncetion pads) on the wiring substrate 100 through conductive wires 130 (first or second conductive wires), respectively. Further, a reinforcing substrate 400 such as a silicon substrate is disposed or mounted on the upper surfaces of the first and second semiconductor chips 200 and 300 through an adhesive member 410 such as a DAF so as to straddle or bridge the first and second semiconductor chips 200 and 300. The upper side of the wiring substrate 100 is sealed with a sealing resin 140, while metal balls 160 are respectively attached to the lands 150 on the lower side thereof.

In this manner, by providing the reinforcing substrate 400 so as to straddle the semiconductor chips 200 and 300 which are mounted on the wiring substrate 100 so as to be spaced apart from each other, it is possible to suppress the occurrence of warpage or torsion in a region between the semiconductor chips 200 and 300. Although the reinforcing substrate 400 is disposed or mounted on the upper surfaces of the first and second semiconductor chips 200 and 300 through the single adhesive member 410, the reinforcing substrate 400 may be stacked so as to straddle the first and second semiconductor chips 200 and 300 via first and second adhesive member (spacer). That is, the first adhesive member (spacer) may be disposed between the first semiconductor chip 200 and the reinforcing substrate 400, and the second adhesive member (spacer) may be disposed between the second semiconductor chip 300 and the reinforcing substrate 400.

Even if concave warpage is assumed as warpage of the semiconductor device 1000, since the reinforcing substrate 400 is disposed, the amount of the sealing resin 140 for molding is reduced corresponding thereto and thus it is possible to further reduce the amount of warpage also from this aspect.

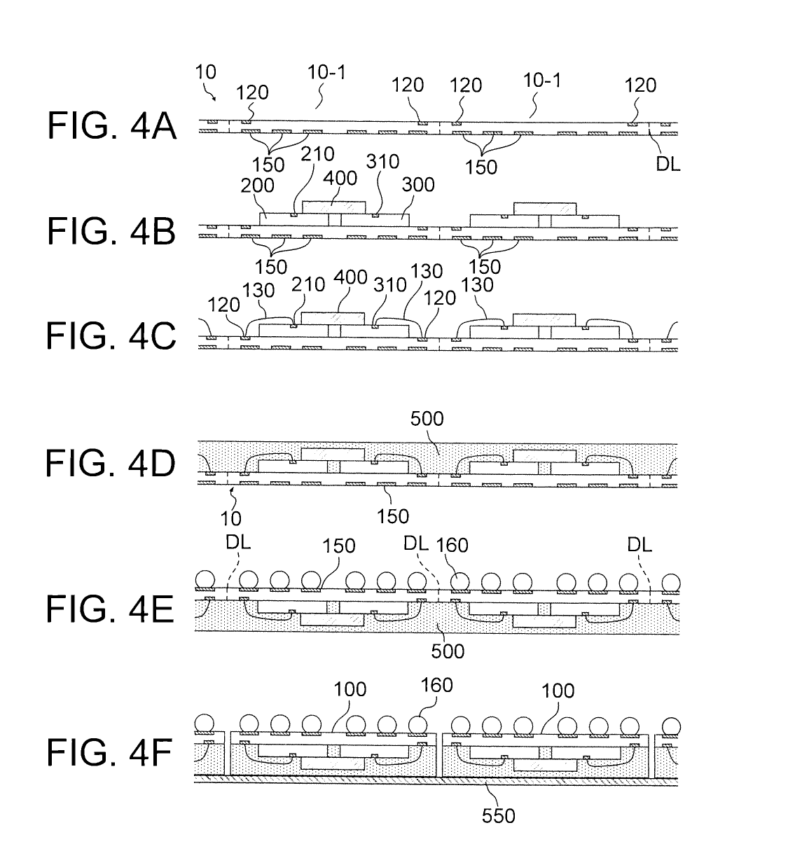

FIGS. 4A to 4F are schematic cross-sectional views for explaining the assembly flow of the semiconductor device 1000 of the first embodiment.

As shown in FIG. 4A, a plurality of product forming portions 10-1 are arranged in a matrix on one side of a wiring mother substrate 10. A plurality of connection pads 120 are formed on the product forming portion 10-1 side of the wiring mother substrate 10 (on one side of the product forming portions 10-1). A plurality of lands 150 are formed on the other side of the wiring mother substrate 10 (on the other side of the product forming portions 10-1) and are electrically connected to the corresponding connection pads 120 by wiring (illustration omitted). As described with reference to FIG. 3, the wiring mother substrate 10 comprises an insulating base member and insulating films formed on both surfaces of the insulating base member, but illustration thereof is omitted herein.

Then, as shown in FIG. 4B, first and second semiconductor chips 200 and 300 are mounted side by side on each of the product forming portions 10-1 of the wiring mother substrate 10 through adhesive members such as DAFs (illustration omitted), respectively. The first and second semiconductor chips 200 and 300 are mounted on each product forming portion 10-1 so as to be aligned in a direction perpendicular to a direction of injection of a molten resin in molding (a direction perpendicular to the drawing plane), which will be described later. In other words, the injection of the molding resin in molding is carried out in a direction perpendicular to an arrangement direction of the first and second semiconductor chips 200 and 300. Such a direction is shown in FIG. 9 by an arrow.

Thereafter, a reinforcing substrate 400 such as a silicon substrate is disposed so as to straddle the first and second semiconductor chips 200 and 300. The reinforcing substrate 400 is mounted on the first and second semiconductor chips 200 and 300 through an adhesive member such as a DAF (illustration omitted) such that electrode pads 210 and 310 formed on one side of the first and second semiconductor chips 200 and 300, respectively, are exposed.

Then, as shown in FIG. 4C, the electrode pads 210 and 310 of the first and second semiconductor chips 200 and 300 and the connection pads 120 formed on each product forming portion 10-1 of the wiring mother substrate 10 are wire-bonded to each other through conductive wires 130, respectively. Au or Cu, for example, is used as the wires 130.

The wire bonding is carried out in the same manner on the semiconductor chip 200 side and the semiconductor chip 300 side. First, a wire projecting from the tip of a capillary of a wire bonding apparatus (not illustrated) is melted by a torch to form a ball at the tip of the wire. Then, for example, on the semiconductor chip 200 side, the wire formed with the ball at its tip is moved by the capillary onto the electrode pad 210 of the semiconductor chip 200 and then is subjected to thermosonic bonding, thereby carrying out first bonding. Subsequently, the wire is moved by the capillary onto the connection pad 120 of the wiring mother substrate 10 so that the wire forms a predetermined loop, and then is subjected to thermosonic bonding, thereby carrying out second bonding. Then, by clamping and pulling the wire, the wire is cut off at its rear end. In this manner, the wire 130 is stretched between the electrode pad 210 of the semiconductor chip 200 and the connection pad 120 of the wiring mother substrate 10 for electrical connection therebetween. This fully applies to the semiconductor chip 300 side as well.

In the case where there is a possibility that the capillary is brought into contact with the reinforcing substrate 400 in wire bonding, the reinforcing substrate 400 may be mounted on the first and second semiconductor chips 200 and 300 to straddle them after the wire bonding.

Then, as shown in FIG. 4D, a sealer 500 in the form of an insulating sealing resin such as a thermosetting epoxy resin is formed so as to integrally cover the one side of all the product forming portions 10-1 of the wiring mother substrate 10. The sealer 500 is formed, for example, in the following manner. First, the wiring mother substrate 10 is clamped between upper and lower molds of a transfer molding machine (not illustrated) and then a molten resin is injected under pressure into a cavity, formed between the upper and lower molds, through a gate. After the cavity is filled with the molten resin, the molten resin is thermally cured so that the sealer 500 is formed so as to cover at least the semiconductor chips 200 and 300 and the wires 130, preferably including the reinforcing substrates 400. Herein, since, as described above, the first and second semiconductor chips 200 and 300 are mounted on each product forming portion 10-1 so as to be aligned in the direction perpendicular to the molten resin injection direction, a space between the semiconductor chips extends along the molten resin injection direction. As a consequence, the molten resin is efficiently injected into the space between the semiconductor chips and thus it is possible to reduce the occurrence of voids in the space between the semiconductor chips.

Then, as shown in FIG. 4E, metal balls 160 are respectively mounted on the lands 150 formed on the other side of the wiring mother substrate 10 (on the other side of the product forming portions 10-1). A solder, for example, is used as the metal balls 160. Using a non-illustrated ball mounter, the metal balls 160 are precisely mounted on the lands 150 which are arranged in a lattice pattern on the other side of the product forming portions 10-1. Specifically, using a mounting tool formed with a plurality of suction holes, the metal balls 160 made of the solder are held by the suction holes and then the held metal balls 160 are collectively placed on the lands 150 through a flux. After the metal balls 160 are placed on the lands 150, the wiring mother substrate 10 is reflowed at a predetermined temperature so that the metal balls 160 are fixedly mounted on the lands 150, respectively.

Then, as shown in FIG. 4F, using a non-illustrated dicing machine, the wiring mother substrate 10 is diced along dicing lines DL shown in broken lines (FIG. 4E) so as to be separated per product forming portion (wiring substrate). The dicing of the wiring mother substrate 10 is carried out in the following manner. First, the sealer 500 of the wiring mother substrate 10 is bonded to a dicing tape 550, thereby supporting the wiring mother substrate 10 by the dicing tape 550. Then, the wiring mother substrate 10 is diced longitudinally and laterally along the dicing lines DL into a plurality of wiring substrates 100 using a dicing blade. After the completion of the dicing, the wiring substrate 100 is picked up from the dicing tape 550, thereby obtaining the semiconductor device 1000 shown in FIG. 3. Since the reinforcing substrate 400 is disposed so as to straddle the semiconductor chips 200 and 300 arranged side by side, it is possible to reduce warpage or torsion of the wiring substrate 100 so that it is possible to reduce the conveyance failure of the wiring substrates 100 and thus to improve the semiconductor device manufacturing yield.

### Second Embodiment

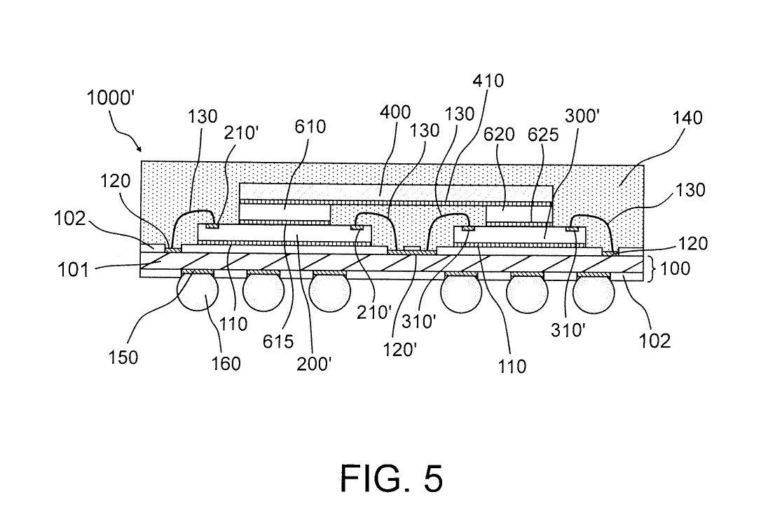

FIG. 5 is a cross-sectional view showing a schematic structure of a semiconductor device 1000′ according to a second embodiment of the present invention. In FIG. 5, the same reference numerals are assigned to the same members as those shown in FIG. 3.

In the semiconductor device 1000′ according to the second embodiment, as in the first embodiment, first and second semiconductor chips 200′ and 300′ are mounted side by side so as to be spaced apart from each other on one surface of a wiring substrate 100 in its left and right regions, respectively. In the second embodiment, electrode pads 210′ and 210′ of the first semiconductor chip 200′ are disposed in chip peripheral regions (regions along two opposite sides) of the first semiconductor chip 200′ and are electrically connected to connection pads 120 and 120′ of the wiring substrate 100 through conductive wires 130 and 130, respectively. Likewise, electrode pads 310′ and 310′ of the second semiconductor chip 300′ are disposed in chip peripheral regions of the second semiconductor chip 300′ and are electrically connected to connection pads 120 and 120′ of the wiring substrate 100 through conductive wires 130 and 130, respectively. In the second embodiment, the connection pads 120′ disposed between the first and second semiconductor chips 200′ and 300′ are each common to the first and second semiconductor chips 200′ and 300′.

In the second embodiment, spacer substrates 610 and 620 are mounted on the first and second semiconductor chips 200′ and 300′ through adhesive members 615 and 625 such as DAFs, respectively. Then, through the spacer substrates 610 and 620, a reinforcing substrate 400 such as a silicon substrate is disposed so as to straddle the first and second semiconductor chips 200′ and 300′. Numerals 110 and 410 each denote an adhesive member such as a DAF. In the second embodiment, the reinforcing substrate 400 is mounted on the first and second semiconductor chips 200′ and 300′ through the spacer substrates 610 and 620, respectively, so as to straddle the first and second semiconductor chips 200′ and 300′. According to this structure, it is possible to allow the wires 130 to be present in a region between the first and second semiconductor chips 200′ and 300′ and further, as in the first embodiment, it is possible to reduce warpage or torsion of the wiring substrate 100 due to the first and second semiconductor chips 200′ and 300′ which are arranged side by side.

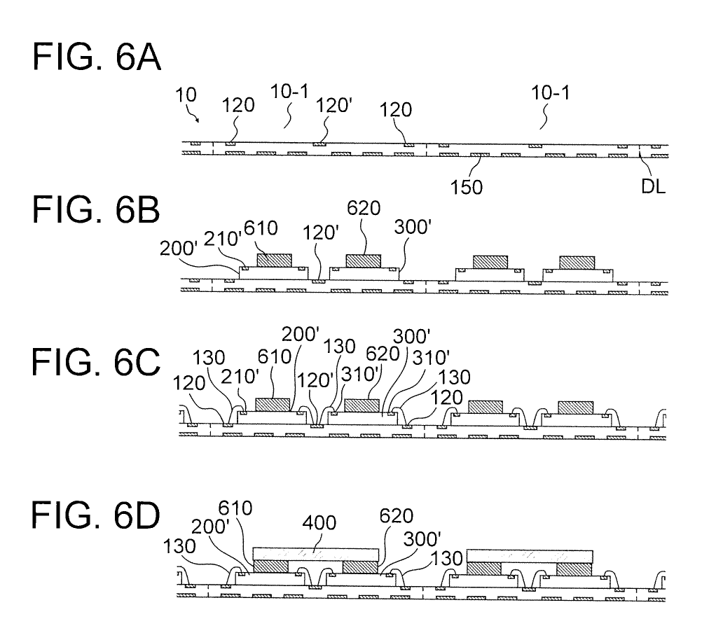

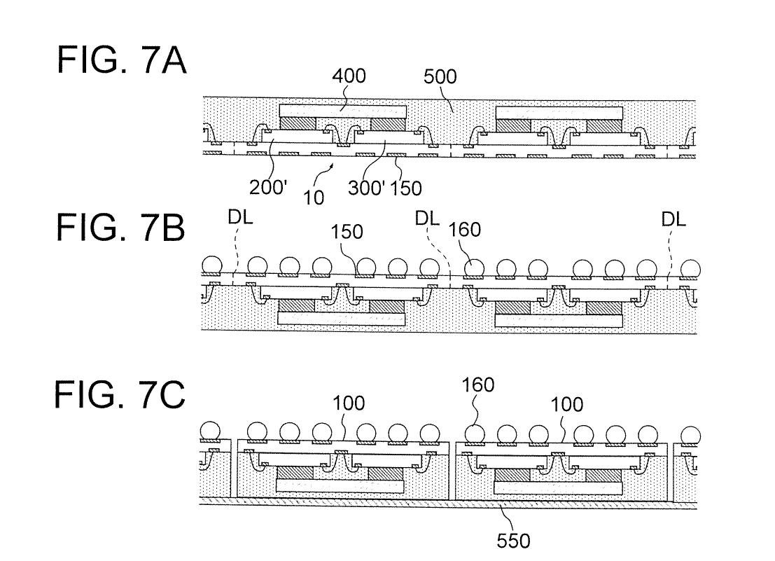

FIGS. 6A to 6D and FIGS. 7A to 7C are schematic cross-sectional views for explaining the assembly flow of the semiconductor device 1000′ according to the second embodiment.

The assembly flow of the second embodiment is the same as the assembly flow of the first embodiment except for a process of mounting the spacer substrates 610 and 620.

As shown in FIG. 6A, a plurality of product forming portions 10-1 are arranged in a matrix on one side of a wiring mother substrate 10. A plurality of connection pads 120 and 120′ are formed on the product forming portion 10-1 side of the wiring mother substrate 10 (on one side of the product forming portions 10-1). A plurality of lands 150 are formed on the other side of the wiring mother substrate 10 (on the other side of the product forming portions 10-1) and are electrically connected to the corresponding connection pads 120 and 120′ by wirings such as via holes (illustration omitted).

Then, as shown in FIG. 6B, first and second semiconductor chips 200′ and 300′ are mounted side by side with a space therebetween on each of the product forming portions 10-1 of the wiring mother substrate 10 through adhesive members 110 and 110 such as DAFs (FIG. 5), respectively. The first and second semiconductor chips 200′ and 300′ are mounted on each product forming portion 10-1 so as to be aligned in a direction perpendicular to a direction of injection of a molten resin in molding, which will be described later.

Thereafter, first and second spacer substrates 610 and 620 are stacked on the first and second semiconductor chips 200′ and 300′, respectively. The first and second spacer substrates 610 and 620 are stacked on the first and second semiconductor chips 200′ and 300′ through adhesive members 615 and 625 such as DAFs (FIG. 5), respectively, such that electrode pads 210′ and 310′ formed in peripheral regions of the first and second semiconductor chips 200′ and 300′, respectively, are exposed. Like a later-described reinforcing substrate 400 or the reinforcing substrate 400 in the first embodiment, each of the first and second spacer substrates 610 and 620 is a silicon substrate. The first and second spacer substrates 610 and 620 are respectively disposed between the semiconductor chips 200′ and 300′ and the reinforcing substrate 400 to contribute to suppressing warpage of a wiring substrate 100 (FIG. 5) and, therefore, the size of each spacer substrate is preferably as large as possible.

Then, as shown in FIG. 6C, the electrode pads 210′ and 310′ of the first and second semiconductor chips 200′ and 300′ and the connection pads 120 and 120′ formed on each product forming portion 10-1 of the wiring mother substrate 10 are wire-bonded to each other through conductive wires 130, respectively. Au or Cu, for example, is used as the wires 130.

The wire bonding is carried out in the same manner on the semiconductor chip 200′ side and the semiconductor chip 300′ side. First, a wire projecting from the tip of a capillary of a wire bonding apparatus (not illustrated) is melted by a torch to form a ball at the tip of the wire. Then, for example, on the semiconductor chip 200′ side, the wire formed with the ball at its tip is moved by the capillary onto the electrode pad 210′ of the semiconductor chip 200′ and then is subjected to thermosonic bonding, thereby carrying out first bonding. Subsequently, the wire is moved by the capillary onto the connection pad 120 (120′) of the wiring mother substrate 10 so that the wire forms a predetermined loop, and then is subjected to thermosonic bonding, thereby carrying out second bonding. Then, by clamping and pulling the wire, the wire is cut off at its rear end. In this manner, the wire 130 is stretched between the electrode pad 210′ of the semiconductor chip 200′ and the connection pad 120 (120′) of the wiring mother substrate 10 for electrical connection therebetween. This fully applies to the semiconductor chip 300′ side as well.

In the case where there is a possibility that the capillary is brought into contact with the first and second spacer substrates 610 and 620 in wire bonding, the first and second spacer substrates 610 and 620 may be stacked on the first and second semiconductor chips 200′ and 300′ after the wire bonding.

Then, as shown in FIG. 6D, a reinforcing substrate 400 such as a silicon substrate is disposed so as to straddle the first and second spacer substrates 610 and 620. The reinforcing substrate 400 is mounted on the first and second spacer substrates 610 and 620 through an adhesive member 410 such as a DAF (FIG. 5).

Then, as shown in FIG. 7A, a sealer 500 in the form of an insulating sealing resin such as a thermosetting epoxy resin is formed so as to integrally cover the one side of all the product forming portions 10-1 of the wiring mother substrate 10. The sealer 500 is formed, for example, in the following manner. First, the wiring mother substrate 10 is clamped between upper and lower molds of a transfer molding machine (not illustrated) and then a molten resin is injected under pressure into a cavity, formed between the upper and lower molds, through a gate. After the cavity is filled with the molten resin, the molten resin is thermally cured so that the sealer 500 is formed so as to cover at least the semiconductor chips 200′ and 300′ and the wires 130, preferably including the reinforcing substrates 400. Herein, since, as described above, the first and second semiconductor chips 200′ and 300′ are mounted on each product forming portion 10-1 so as to be aligned in the direction perpendicular to the molten resin injection direction, a space between the semiconductor chips extends along the molten resin injection direction. As a consequence, the molten resin is efficiently injected into the space between the semiconductor chips and thus it is possible to reduce the occurrence of voids in the space between the semiconductor chips.

Then, as shown in FIG. 7B, metal balls 160 are respectively mounted on the lands 150 formed on the other side of the wiring mother substrate 10 (on the other side of the product forming portions 10-1). A solder, for example, is used as the metal balls 160. Using a non-illustrated ball mounter, the metal balls 160 are precisely mounted on the lands 150 which are arranged in a lattice pattern on the other side of the wiring mother substrate 10. Specifically, using a mounting tool formed with a plurality of suction holes, the metal balls 160 made of the solder are held by the suction holes and then the held metal balls 160 are collectively placed on the lands 150 through a flux. After the metal balls 160 are placed on the lands 150, the wiring mother substrate 10 is reflowed at a predetermined temperature so that the metal balls 160 are fixedly mounted on the lands 150, respectively.

Then, as shown in FIG. 7C, using a non-illustrated dicing machine, the wiring mother substrate 10 is diced along dicing lines DL shown in broken lines (FIG. 7B) so as to be separated per product forming portion (wiring substrate). The dicing of the wiring mother substrate 10 is carried out in the following manner. First, the sealer 500 of the wiring mother substrate 10 is bonded to a dicing tape 550, thereby supporting the wiring mother substrate 10 by the dicing tape 550. Then, the wiring mother substrate 10 is diced longitudinally and laterally along the dicing lines DL into a plurality of wiring substrates 100 using a dicing blade. After the completion of the dicing, the wiring substrate 100 is picked up from the dicing tape 550, thereby obtaining the semiconductor device 1000′ shown in FIG. 5. Since the reinforcing substrate 400 is mounted so as to straddle the semiconductor chips 200′ and 300′ arranged side by side, it is possible to reduce warpage or torsion of the wiring substrate 100 so that it is possible to reduce the conveyance failure of the wiring substrates 100 and thus to improve the semiconductor device manufacturing yield.

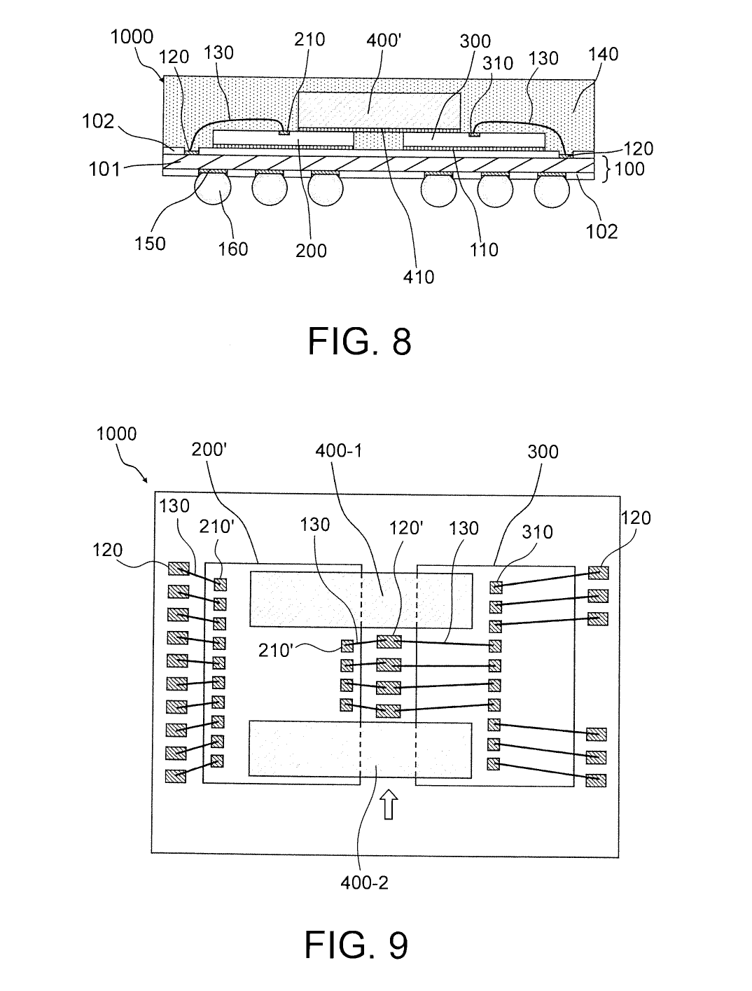

FIG. 8 is a cross-sectional view showing a third embodiment as a modification of the first embodiment. In FIG. 8, the same reference numerals are assigned to the same members as those shown in FIG. 3.

In the third embodiment, the thickness of a reinforcing substrate 400′ which is disposed so as to straddle first and second semiconductor chips 200 and 300 is set to be greater than the thickness of each semiconductor chip, for example, greater than 70 μm. This makes it possible to enhance the rigidity of the reinforcing substrate 400′ and thus to suppress warpage or torsion of a wiring substrate 100 more satisfactorily. This third embodiment may be combined with the second embodiment.

In each of the above-mentioned embodiments, the description has been given of the case where the single reinforcing substrate is provided between the two semiconductor chips. However, depending on the layout of electrode pads formed on a semiconductor chip, a plurality of reinforcing substrates may be provided between two semiconductor chips as shown in FIG. 9 as a first modification. Specifically, in FIG. 9, a first semiconductor chip 200′ is configured such that a plurality of electrode pads 210′ formed in the middle of an edge, adjacent to a second semiconductor chip 300, of the first semiconductor chip 200′ are wire-bonded to connection pads 120′ formed between the first and second semiconductor chips 200′ and 300. On the other hand, the second semiconductor chip 300 is configured such that some, at a middle portion, of electrode pads 310 arranged in one row along the center line of the second semiconductor chip 300 are wire-bonded to the connection pads 120′ formed between the first and second semiconductor chips 200′ and 300. Accordingly, two reinforcing substrates 400-1 and 400-2 are provided between the first and second semiconductor chips 200′ and 300 to thereby exclude a region of the wire bonding. Naturally, three or more reinforcing substrates may be provided. This first modification may be combined with the second or third embodiment. In FIG. 9, the same reference numerals are assigned to the same members as those shown in FIG. 3.

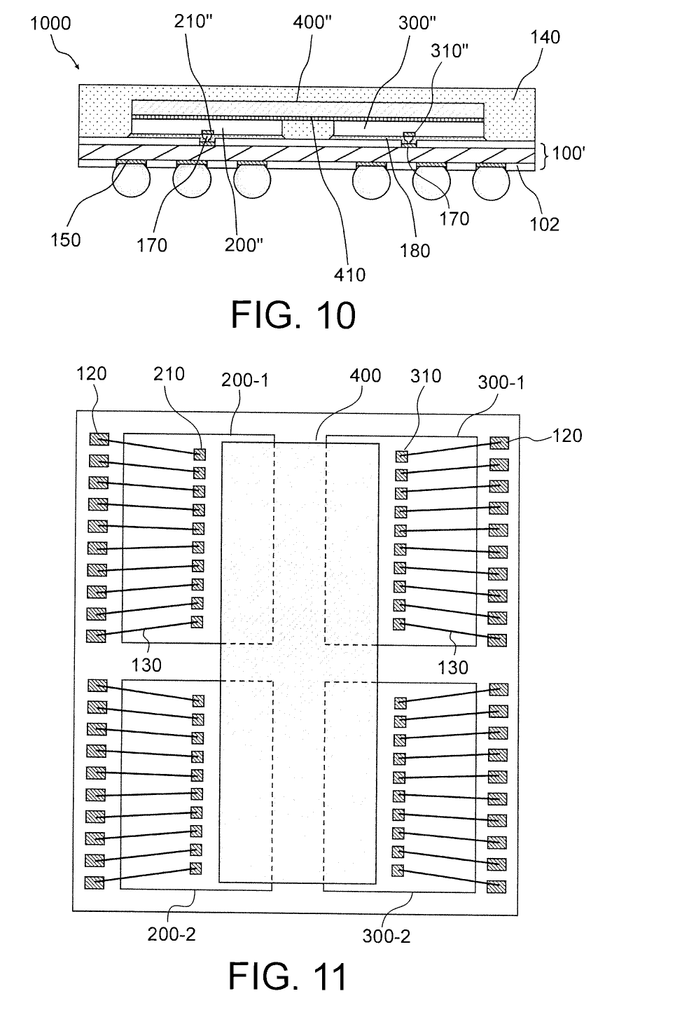

In each of the above-mentioned embodiments, the description has been given of the case where the reinforcing substrate is disposed on the two semiconductor chips which are face-up mounted on the wiring substrate. However, as shown in FIG. 10 as a second modification, a reinforcing substrate 400″ may be disposed, through an adhesive member 410 such as a DAF, on first and second semiconductor chips 200″ and 300″ which are flip-chip bonded to a wiring substrate 100′. Specifically, the first and second semiconductor chips 200″ and 300″ are mounted on the wiring substrate 100′ through an underfill 180 such that flip-chip bonding is carried out between electrode pads 210″ and 310″ formed on the lower side of the first and second semiconductor chips 200″ and 300″ and bump electrodes 170 disposed on the wiring substrate 100′. In the case of such flip-chip bonding, the reinforcing substrate 400″ can be disposed over the entire surfaces of the two semiconductor chips 200″ and 300″ and thus it is possible to suppress warpage or torsion of the wiring substrate 100′ more satisfactorily. This second modification may be combined with the third embodiment. In FIG. 10, the same reference numerals are assigned to the same members as those shown in FIG. 3.

In each of the above-mentioned embodiments, the reinforcing substrate is mounted so as to straddle the two semiconductor chips. However, as shown in FIG. 11 as a third modification, a single reinforcing substrate 400 may be disposed so as to straddle three or more semiconductor chips 200-1, 200-2, 300-1, and 300-2. This third modification may be combined with the second or third embodiment or with the second modification. In FIG. 11, the same reference numerals are assigned to the same members as those shown in FIG. 3.

While the present invention has been described with reference to the embodiments, it is needless to say that the invention is not limited thereto and that various changes can be made without departing from the spirit and scope of the present invention.

The whole or part of the exemplary embodiments disclosed above can be described as the following supplementary notes, but is not limited to them.

### (Note 1)

A semiconductor device manufacturing method comprising:
disposing, side by side, at least two semiconductor chips on a wiring substrate; and
disposing at least one reinforcing substrate so as to straddle at least portions of the two semiconductor chips.

### (Note 2)

The semiconductor device manufacturing method according to Note 1, wherein the reinforcing substrate is disposed on the two semiconductor chips so as not to lie over any of first electrode pads respectively formed on upper surfaces of the two semiconductor chips,
wire bonding is carried out between each of the first electrode pads of the two semiconductor chips and a first connection pad of the wiring substrate before or after disposing the reinforcing substrate, and
at least the two semiconductor chips and bonded wires are sealed with a resin.

### (Note 3)

The semiconductor device manufacturing method according to Note 2, wherein wire bonding is carried out between a second electrode pad of each of the two semiconductor chips and a second connection pad formed on the wiring substrate at its portion between the two semiconductor chips and then the reinforcing substrate is disposed on the two semiconductor chips through spacer substrates, respectively, so that a wire is bonded between the second electrode pad of each of the two semiconductor chips and the second connection pad of the wiring substrate in a space which is formed on a lower side of the reinforcing substrate by the spacer substrates.

### (Note 4)

The semiconductor device manufacturing method according to Note 1, wherein the reinforcing substrate has a thickness which is greater than that of each of the two semiconductor chips.

### (Note 5)

The semiconductor device manufacturing method according to Note 1, wherein the two semiconductor chips are flip-chip bonded to the wiring substrate and the reinforcing substrate is disposed so as to straddle the entire surfaces of the two semiconductor chips.

### (Note 6)

The semiconductor device manufacturing method according to Note 1, wherein the reinforcing substrate is disposed so as to straddle the three or more semiconductor chips.

### (Note 7)

The semiconductor device manufacturing method according to Note 2, wherein when sealing with the resin, a molten resin is injected in a direction perpendicular to an arrangement direction of the at least two semiconductor chips.

What is claimed is:

1. A semiconductor device comprising:
a wiring substrate;
at least two semiconductor chips mounted on the wiring substrate; and
at least one reinforcing substrate disposed so as to straddle at least portions of the two semiconductor chips.

2. The semiconductor device according to claim 1, wherein the reinforcing substrate is disposed on the two semiconductor chips through spacer substrates, respectively, and wherein a wire is bonded between an electrode pad of each of the two semiconductor chips and a connection pad of the wiring substrate in a space which is formed on a lower side of the reinforcing substrate by the spacer substrates.

3. The semiconductor device according to claim 1, wherein the reinforcing substrate has a thickness which is greater than that of each of the two semiconductor chips.

4. The semiconductor device according to claim 1, wherein the two semiconductor chips are flip-chip bonded to the wiring substrate and the reinforcing substrate is disposed so as to straddle the entire surfaces of the two semiconductor chips.

5. The semiconductor device according to claim 1, wherein the reinforcing substrate is disposed so as to straddle the three or more semiconductor chips.

6. The semiconductor device according to claim 1, wherein one side of the wiring substrate including the at least two semiconductor chips and the reinforcing substrate is sealed with a resin.

7. The semiconductor device according to claim 6, wherein the at least two semiconductor chips are arranged in a direction perpendicular to a molten resin injection direction when sealing with the resin.

8. A semiconductor device comprising:
a wiring substrate including an upper surface;
a first semiconductor chip mounted over the upper surface of the wiring substrate;
a second semiconductor chip having a thickness that is substantially equal to that of the first semiconductor chip and mounted over the upper surface of the wiring substrate, the second semiconductor chip being apart from the first semiconductor chip, and a silicon substrate stacked so as to straddle the first and second semiconductor chips.

9. The semiconductor device according to claim 8, wherein the wiring substrate includes first and second connection pads formed on the upper surface,
the first semiconductor chip includes a first surface, a second surface opposite to the first surface and a first electrode formed on the first surface, the first electrode is electrically connected to the first connection pad of the wiring substrate, and
the second semiconductor chip includes a third surface, a fourth surface opposite to the third surface and a second electrode formed on the third surface, the second electrode is electrically connected to the second connection pad of the wiring substrate.

10. The semiconductor device according to claim 9, wherein the first semiconductor chip is mounted over the upper surface of the wiring substrate so that the second surface faces the wiring substrate, the first electrode is electrically connected to the first connection pad via a first conductive wire, and
the second semiconductor chip mounted over the upper surface of the wiring substrate so that the fourth surface faces the wring substrate, the second electrode is electrically connected to the second connection pad via a second conductive wire.

11. The semiconductor device according to claim 8, wherein the silicon substrate has a thickness that is greater than that of each of the first and second semiconductor chips.

12. The semiconductor device according to claim 9, wherein the first semiconductor chip is mounted over the upper surface of the wiring substrate so that the first surface faces the wiring substrate, the first electrode is electrically connected to the first conductive pad via a first bump and
the second semiconductor chip is mounted over the upper surface of the wiring substrate so that the third surface faces the wiring substrate, the second electrode is electrically connected to the second conductive pad via a second bump.

13. The semiconductor device according to claim 8, wherein the silicon substrate is stacked so as to straddle the first and second semiconductor chips via first and second spacer, the first spacer being disposed between the first semiconductor chip and the silicon substrate, and the second spacer being disposed between the second semiconductor chip and the silicon substrate.

14. The semiconductor device according to claim 9, wherein the first and second connection pad is disposed between the first and second semiconductor chips.

15. The semiconductor device according to claim 8, further comprising:
a sealing resin provided over the upper surface of the wiring substrate to cover the first semiconductor chip, the second semiconductor chip and the silicon substrate.

16. The semiconductor device according to claim 8, wherein the second semiconductor chip is apart from the first semiconductor chip by a distance of more than 2.5 mm.

17. A semiconductor device comprising:
a wiring substrate including an upper surface and a connection pad formed on the upper surface;
a first semiconductor chip mounted over the upper surface of the wiring substrate;
a second semiconductor chip mounted over the upper surface of the wiring substrate so as to form a space between the first and second semiconductor chips, the second semiconductor chip having a thickness that is substantially equal to that of the first semiconductor chip;
a silicon substrate stacked over the first and second semiconductor chips, the space being disposed between the wiring substrate and the silicon substrate; and
a sealing resin provided over the upper surface of the wiring substrate to cover the first semiconductor chip, the second semiconductor chip and the silicon substrate, the space being filled with the sealing resin.

18. The semiconductor device according to claim 17, wherein the wiring substrate includes a connection pad formed on the upper surface, the connection pad is arranged between the first and second semiconductor chips, and the connection pad is electrically connected to each of the first and second semiconductor chips.

19. The semiconductor device according to claim 17, wherein the silicon substrate has a thickness that is greater than that of each of the first and second semiconductor chips.

20. The semiconductor device according to claim 16, wherein a width of the space between the first and second semiconductor chips is 2.5 mm or more.
